(19) United States
(12) Patent Application Publication
(10) Pub. No.: US 2004/0256715 A1
(43) Pub. Date: Dec. 23, 2004

(54) Wiring board, semiconductor device and process of fabricating wiring board

(75) Inventor: Yoshikatsu Seki, Nagano-shi (JP)

Correspondence Address: STAAS & HALSEY LLP, SUITE 700, 1201 NEW YORK AVENUE, N.W., WASHINGTON, DC, 20005, US

(73) Assignee: SHINKO ELECTRIC INDUSTRIES CO., LTD., Nagano (JP)

(21) Appl. No.: 10/864,334

(22) Filed: Jun. 10, 2004

(30) Foreign Application Priority Data
Jun. 17, 2003 (JP) 2003-172036

(51) Int. Cl. H01L 23/02; H01L 21/48

(52) U.S. Cl. 257/698; 257/700; 438/108; 438/617

(57) ABSTRACT

A wiring board comprises: a substrate having a surface on which a plurality of connecting electrodes are arranged; an interposer provided with via conductors arranged so as to conform to an arrangement of a plurality of electrodes formed on an electrode forming surface of a semiconductor element to be mounted, so that, when the semiconductor element is mounted on the substrate, the respective electrodes of the semiconductor element are electrically connected to the respective connecting electrodes of the substrate through respective via conductors of the interposer. The interposer comprises a plurality of insulating layers stacked or laminated in thickness direction thereof, each layer having a plurality of filled vias penetrating in a thickness direction thereof, to form columns.

### BACKGROUND OF THE INVENTION

1. Field of the Invention

The present invention relates to a wiring board, a semiconductor device and a process of fabricating the wiring board and, in particular, to a wiring board, a semiconductor device and a process of fabricating the wiring board in which the thermal stress generated between a semiconductor element and a substrate for mounting the semiconductor element is reduced.

2. Description of the Related Art

A semiconductor element, such as a CPU, having a large calorific value is generally mounted on a board using the flip chip bonding method. In the flip chip bonding, the electrodes of the semiconductor element and the connecting electrodes of the substrate are connected directly to each other through solder bumps or the like and, therefore, the thermal stress between the semiconductor element and the substrate poses a problem.

In the conventional flip chip bonding method, the space between the semiconductor element and the substrate is filled with an underfill resin and the resin is solidified to secure the electrical connection between the electrodes of semiconductor element and the connecting pads of substrate against a thermal stress which may be generated between the semiconductor element and the substrate (see U.S. 2001/0003049 A1 corresponding to Japanese Unexamined Patent Publication No. 10-79362).

With the increase in the thermal stress between the semiconductor element and the substrate, however, the underfill resin between the semiconductor element and the substrate or the surface resin layer of the substrate develop cracks. In order to solve the problem caused by the thermal stress generated between the semiconductor element and the substrate, the thermal stress generated between the semiconductor element and the substrate is reduced or relaxed by selecting a substrate having a thermal expansion coefficient as close to that of the semiconductor element as possible or the connection electrodes of the semiconductor element are so structured as to absorb the thermal stress between the semiconductor element and the substrate.

To meet the recent demand for a further increased operating speed and a higher integration of the semiconductor element, however, the insulating layer of the semiconductor element has come to be formed of a material having a low dielectric constant. Thus, the problem is posed that the semiconductor element is reduced in strength or easily separated from the substrate or deformed by the thermal stress generated between the semiconductor element and the substrate.

### SUMMARY OF THE INVENTION

This invention has been achieved to solve these problems, and the object thereof is to provide a wiring board, a semiconductor device and a method of fabricating the wiring board, in which the thermal stress on the semiconductor element is relaxed so that even a semiconductor element reduced in strength as compared with the conventional product or a bulky semiconductor element which could not be mounted on the conventional substrate can be easily mounted to meet the trend toward a higher operating speed and integration of the semiconductor element.

According to the present invention, there is provided a wiring board comprising: a substrate having a surface on which a plurality of connecting electrodes are arranged; an interposer provided with via conductors arranged so as to conform to an arrangement of a plurality of electrodes formed on an electrode forming surface of a semiconductor element to be mounted, so that, when the semiconductor element is mounted on the substrate, the respective electrodes of the semiconductor element are electrically connected to the respective connecting electrodes of the substrate through respective via conductors of the interposer; and the interposer comprising a plurality of insulating layers laminated in thickness direction thereof, each layer having a plurality of filled vias penetrating in a thickness direction thereof, to form columns.

The via connectors of the interposer are electrically connected to the connecting electrodes of the substrate by means of bumps.

The interposer has an element mounting surface on which a plurality of solder bumps are arranged and electrically connected to the respective via conductors. Otherwise, the interposer has an semiconductor element mounting surface on which a plurality of connecting pads are arranged and electrically connected to the via conductors.

According to another aspect of the present invention, there is provided a semiconductor device comprising: a semiconductor element having an electrode forming surface on which of a plurality of electrodes are formed; a substrate having a surface on which a plurality of connecting electrodes are arranged; an interposer provided with via conductors arranged so as to conform to an arrangement of the electrodes of the semiconductor element, so that the semiconductor element is flip-chip mounted in such a manner that the respective electrodes of the semiconductor element are electrically connected to the respective connecting electrodes of the substrate through the respective via conductors of the interposer; and the interposer comprising a plurality of insulating layers laminated in thickness direction thereof, each layer having a plurality of filled vias penetrating in a thickness direction thereof, to form columns.

According to still another aspect of the present invention, there is provided a process for fabricating a wiring board comprising the following steps of: forming a first insulating layer with first via holes and filling the first via holes with first via conductor; forming a second insulating layer on the first insulating layer, forming second insulating layer with second via holes in registry with the first via conductors, and filling the second via holes with second via conductor; and repeating these steps to form an interposer in which the plurality of insulating layers are integrally stacked so that the plurality of conductor vias are mutually and electrically connected with the conductor vias of the adjacent layers in a thinness direction of thus formed laminated body; and abutting the interposer to a substrate in such a manner that the via conductors of the interposer are electrically connected to respective connecting electrodes of the substrate.

According to still another aspect of the present invention, there is provided a process for fabricating a process for fabricating a wiring board comprising the following steps of: preparing a plurality of connection films, each comprising an insulating layer provided with a plurality of conductor vias formed as filled vias penetrating the insulating layer in a thickness direction thereof; and integrally stacking the plurality of connection films in registry with each other to laminate the plurality of insulating layers so that the plurality of conductor vias are mutually and electrically connected with the conductor vias of the adjacent layers in a thinness direction of thus formed laminated body to form an interposer; and abutting the interposer to a substrate in such a manner that the via conductors of the interposer are electrically connected to respective connecting electrodes of the substrate.

### BRIEF DESCRIPTION OF THE DRAWINGS

FIGS. 1(a) to 1(e) are diagrams for explaining the first half of the steps of a method for fabricating an interposer used for the wiring board.

FIGS. 2(a) to 2(d) are diagrams for explaining the last half of the steps of a method for fabricating an interposer used for the wiring board.

FIGS. 3(a) and 3(b) are diagrams for explaining a method of fabricating a wiring board and the state in which the semiconductor element is mounted on the wiring board according to the invention; and FIG. 3(c) shows a modified embodiment;

FIGS. 4(a) to 4(f) are diagrams for explaining the first half of the steps of a second method for fabricating an interposer used for the wiring board.

FIGS. 5(a) and 5(b) are diagrams for explaining the last half of the steps of the second method for fabricating an interposer used for the wiring board.

### DESCRIPTION OF THE PREFERRED EMBODIMENTS

Preferred embodiments of the invention are explained in detail below with reference to the accompanying drawings.

The wiring board according to the invention is characterized in that an interposer is inserted between the semiconductor elements and the substrate to relax the thermal stress occurred between and a substrate such as a printed board and a semiconductor element, and the semiconductor element is mounted on the interposer.

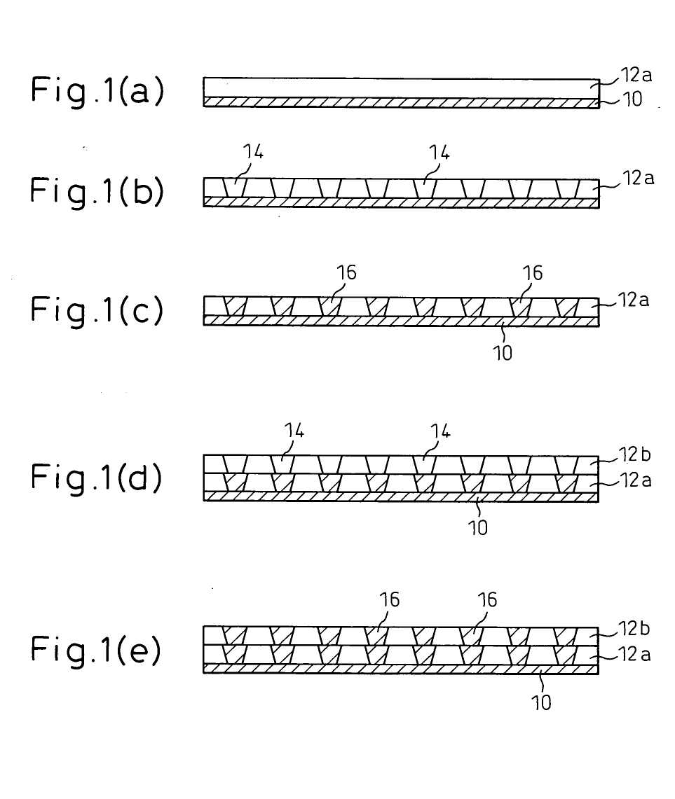

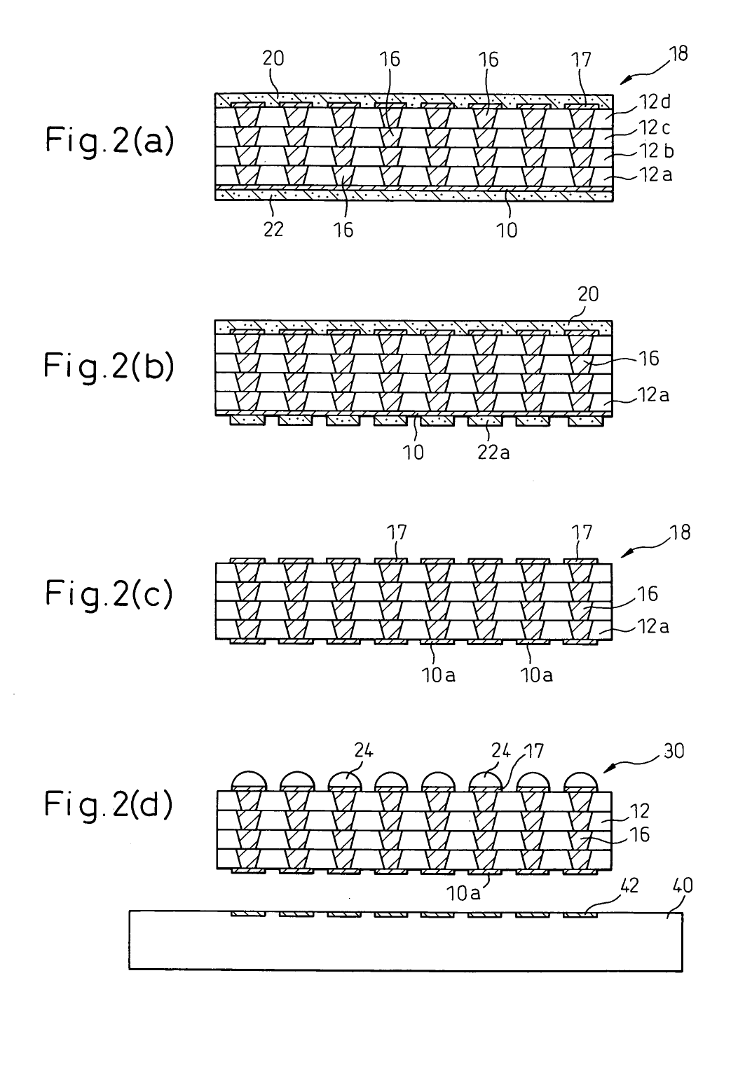

The steps of fabricating the interposer are shown in FIGS. 1(a) to 1(e) and 2(a) to 2(d).

FIG. 1(a) shows the state in which an insulating layer 12a is formed on one surface of a copper foil 10. The insulating layer 12a is formed by lamination of the copper foil 10 with a resin film of a resin material having an electrical insulation characteristic such as polyimide resin.

FIG. 1(b) shows the state in which a plurality of via holes 14 are formed in the insulating layer 12a. In the case where the insulating layer 12a is formed of a photosensitive resin, the via holes 14 can be formed by optical exposure and development while, in the case where the insulating layer 12a is formed of a non-photosensitive resin, on the other hand, the via holes 14 can be formed by laser drilling. The via holes 14 are formed in such a manner that they are exposed to the copper foil 10 at each bottom surface thereof.

FIG. 1(c) shows the state in which the via holes 14 are filled with via conductors 16 of copper, or the like material, by via plating with the copper foil 10 as a plating power feed layer. By filling the via holes 14 with the via conductors 16, the copper foil 10 constituting a lower layer and the via conductors 16 are electrically connected to each other.

FIG. 1(d) shows the state in which, in order to form the via conductors in the upper layer, an insulating layer 12b is formed by lamination on the surface of the insulating layer 12a constituting the first layer and the via holes 14 are formed in the insulating layer 12b.

FIG. 1(e) shows the state in which the via holes 14 constituting the second layer are filled with the via conductors 16 by via plating with the copper foil 10 as a plating power feed layer.

The plurality of via conductors 16 in the second layer are formed at the same planar positions, respectively, as the via conductors 16 in the first layer. The via conductors 16 in the first layer are formed as filled vias. The via holes 14 are thus formed in the insulating layer 12b making up the second layer, and by filling the plating material in the via holes 14, the via conductors 16 making up the second layer are formed in superposition on the via conductors 16 constituting the first layer.

By repeating the processes of FIGS. 1(d) and 1(e) a plurality of times, a stack unit 18 can be formed with the via conductors 16 stacked in columns.

The via conductors 16 formed by being stacked in columns through the insulating layers are electrically connected with the electrodes of the semiconductor element mounted by flip chip bonding. Thus, the via conductors 16 are arranged at the same planar positions, respectively, as the electrodes of the semiconductor element.

FIGS. 2(a) to 2(d) show the processes to form connection pads of an interposer on the surface of the stack unit 18 formed with the via conductors 16 on which the semiconductor element is mounted and on the surface of the stack unit 18 coupled to the substrate 40.

FIG. 2(a) shows the state in which connection pads 17 are formed on the respective via conductors 16 of the uppermost layer 12d, as mentioned later in detail, and resist films 20, 22 are formed by lamination on the upper and lower surfaces of the stack unit 18, respectively. FIG. 2(b) shows the state in which a resist pattern 22a is formed by exposing and developing the resist film 22 on the lower surface of the stack unit 18. The resist pattern 22a is formed in such a manner as to cover the copper foil 10 in the same circular form as prospective pads at positions just under the corresponding via conductors 16 formed in the stack unit 18.

FIG. 2(c) shows the state in which connection pads 10a are formed on the lower surface of the stack unit 18 by etching the copper foil 10 with the resist pattern 22a as a mask. Such a state can be obtained, after forming the connection pads 10a, when the resist film 20 on the upper surface of the stack unit 18 and the resist pattern 22a deposited on the lower surface of the stack unit 18 are etched off.

FIG. 2(d) shows the state in which the solder paste is printed on the connection pads 17 formed on the upper surface of the stack unit 18 and solder bumps 24 are formed by reflow soldering thereby to form an interposer 30. The interposer 30, as shown, is constructed in such a manner that the via conductors 16 are formed in columns through the insulating layers 12 through the thickness of the interposer 30.

According to this embodiment, a pattern of the connection pads 17 is formed in advance, as shown in FIG. 2(a), on the upper surface of the stack unit 18. To form the connection pads 17 on the upper surface of the stack unit 18, a conducting layer is formed and etched into a predetermined pattern on the surface of the uppermost insulating layer 12d, constituting the fourth layer, when plating the via holes 14 are formed in the insulating layer 12d.

As an alternative, with the conducting layer formed on the surface of the insulating layer 12d, a resist film is formed by lamination on each of the upper and lower surfaces of the stack unit 18 and exposed and developed thereby to form the connection pads 10a, 17, respectively, on the respective surfaces of the stack unit 18.

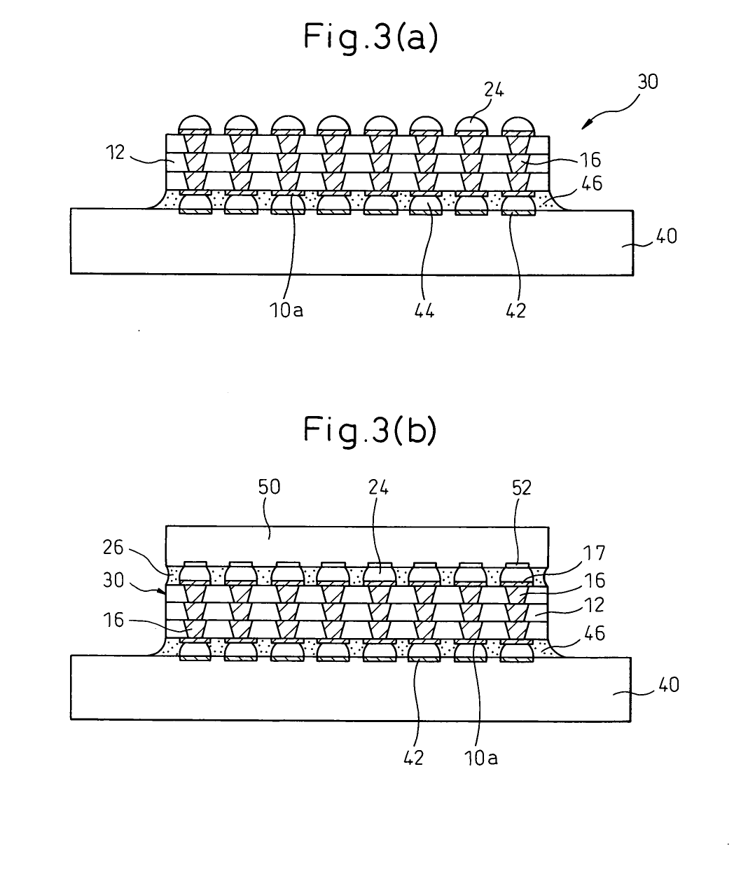

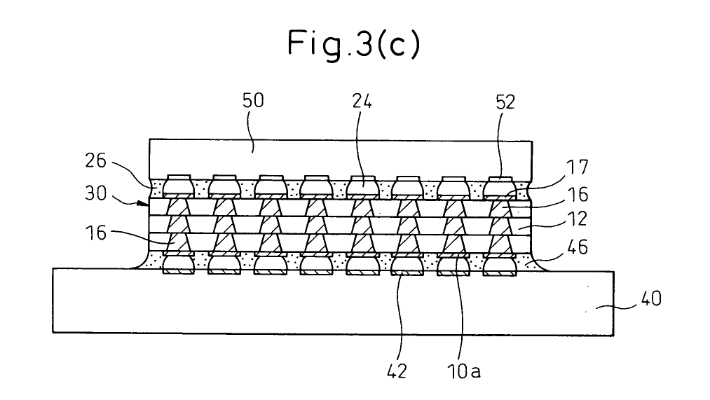

FIGS. 3(a) to 3(b) show the process for forming a wiring board by coupling the substrate 40 with the interposer 30 formed according to the method described above and mounting the semiconductor element on the wiring board thereby to produce a semiconductor device.

FIG. 3(a) shows the state in which the interposer 30 is coupled to the substrate 40 in position. The substrate 40 is formed with connection electrodes 42 at the same planar positions as the connection pads 10a. According to this embodiment, the solder paste is printed on the connection electrodes 42 and solder bumps 44 are formed on the connection electrodes 42 by reflow soldering thereby to couple the interposer 30 with the substrate 40. Numeral 46 designates an underfill resin filled in the gaps of the joint between the interposer 30 and the substrate 40. Nevertheless, it is possible to omit the underfill resin 46.

FIG. 3(b) shows the state in which the semiconductor element 50 is mounted on the wiring board which has been formed by coupling the interposer 30 to the substrate 40. The semiconductor element 50 is mounted, by flip chip bonding, on the element-mounting surface of the interposer 30.

According to this embodiment, the solder bumps 24 are formed in advance on the connection pads 17 of the interposer 30. As an alternative, solder bumps are formed on the electrodes 52 of the semiconductor element 50 instead of forming the solder bumps 24 on the connection pads 17.

The semiconductor element 50 is coupled with the electrodes 52 thereof set in registration with the connection pads 17 formed on the upper surface of the interposer 30. Numeral 26 designates the underfill resin filled between the semiconductor element 50 and the upper surface of the interposer 30. Nevertheless, it is possible to omit the underfill resin 26.

As described above, the semiconductor element 50 is bonded to the interposer 30 in position and thus electrically connected with the respective connection pads 42 of the substrate 40 through the interposer 30.

The interposer 30 is formed, as shown, with the via conductors 16 coupled with each other in columns at positions in registry with the electrodes 52 of the semiconductor element 50, and the insulating layer 12 of the interposer 30 is formed by stacking a plurality of layers of insulating material having the electric insulation characteristic such as polyimide. Therefore, the via conductors 16 and the insulating layer 12 can be readily deformed, thereby functioning as a satisfactory buffer to reduce the thermal stress generated between the semiconductor element 50 and the substrate 40.

By mounting the semiconductor element 50 on the substrate 40 through the interposer 30 as shown in FIG. 3(b), therefore, the thermal stress acting on the semiconductor element 50 can be effectively reduced even in the case where the thermal expansion coefficient of the semiconductor element 50 is different from that of the substrate 40.

As described above, the interposer 30 is constructed of a plurality of insulating layers 12 having the via conductors 16 stacked in columns in order to make the via conductors 16 readily deformable and thereby to improve the function of the insulating layers 12 as a buffer.

The number of stacked layers making up the interposer 30 is adjusted in accordance with the size, etc. of the semiconductor element 50.

It should be noted that in the above-mentioned embodiment, the interposer 30 may be coupled to the substrate 40 in such a manner that the interposer 30 is positioned up-side-down as compared with the those as shown in FIGS. 3(a) and 3(b). Thus, FIG. 3(c) shows such a modified embodiment in which the interposer 30 is positioned up-side-down. The respective steps in the processes for forming the wiring board and the effects of the product are quite the same as the above-mentioned embodiment.

To facilitate understanding, the interposer 30 is shown to have a large thickness. The thickness of the interposer 30 is actually about 200 μm. The provision of the interposer 30, therefore, poses no problem regarding the package thickness.

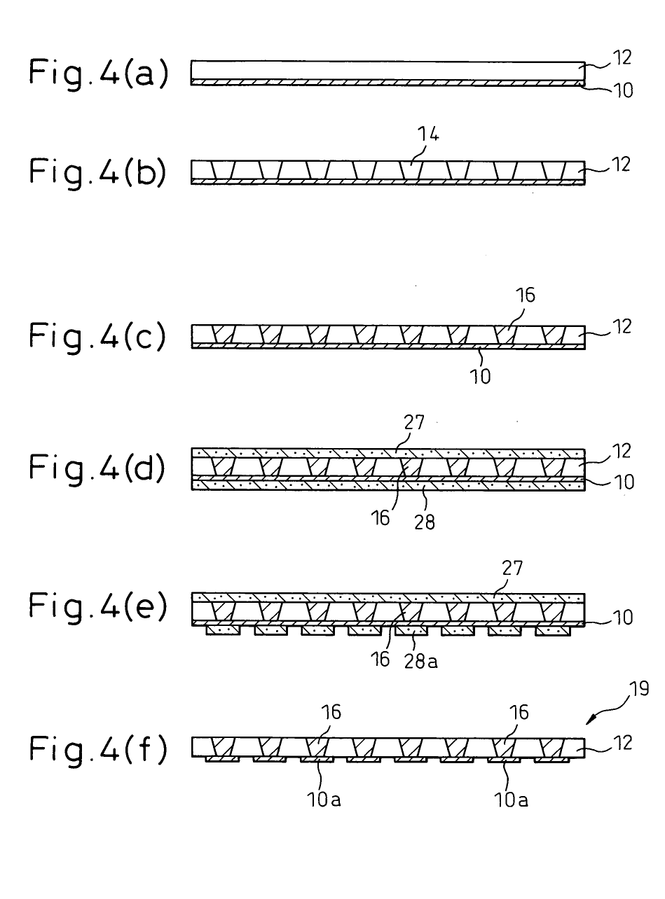

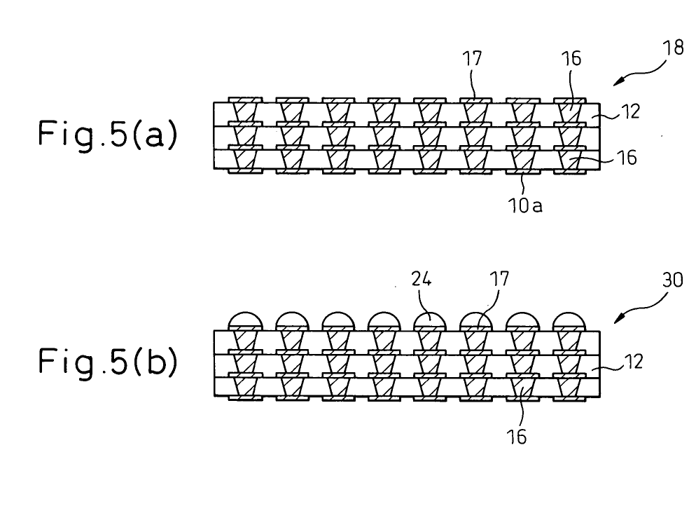

FIGS. 4(a) to 4(f) and 5(a) and 5(b) show another method of fabricating the interposer 30.

FIG. 4(a) shows the state in which an insulating layer 12 is formed on one surface of a copper foil 10, and FIG. 4(b) the state in which a plurality of via holes 14 are formed in the insulating layer 12, in the same manner as the previous embodiment shown in FIGS. 1(a) and 1(b).

FIG. 4(c) shows the state in which the via holes 14 are filled with via conductors 16 by plating with the copper foil 10 as a plating power feed layer.

FIG. 4(d) shows a step characteristic of this embodiment, in which, after filling the via holes 14 with the via conductors 16, the respective surfaces of the insulating layer 12 are covered with resist films 27 and 28, respectively. The resist films 27, 28 are provided for etching the copper foil 10.

FIG. 4(e) shows the state in which the resist film 28 is patterned to form a resist pattern 28a in order to leave the copper foil 10 as connection pads at the same positions as the via conductors 16.

FIG. 4(f) shows the state in which the copper foil 10 is etched with the resist pattern 28a as a mask to produce a connection film 19 including the insulating layer 12 and the connection pads 10a formed on the lower surface (one surface) of the insulating layer 12. The connection film 19 has the via conductors 16 formed through the thickness of the insulating layer 12, and each connection pad 10a electrically connected with the corresponding one of the via conductors 16 is formed on one surface of the particular via conductor 16.

According to this embodiment, a plurality of the connection films 19 formed as described above are collectively stacked in registry with each other thereby to form a stack unit 18 constituting an interposer 30.

FIG. 5(a) shows the state in which the stack unit 18 is formed of a plurality of connection films 19. The connection films 19 each have the via conductors 16 arranged at the same planar positions as the electrodes 52 of the semiconductor element 50 (FIG. 3(b)). The stack unit 18 as shown in FIG. 5(a) is produced by integrally stacking a predetermined number of the connection films 19.

The connection films 19 are arranged and stacked with the connection pads 10a on the same side (the lower side, for example) of each connection film 19. In this way, each layer of the connection films 19 is stacked electrically connected with the corresponding one of the via conductors 16 of adjacent layers through the connection pads 10a.

FIG. 5(b) shows the state in which bumps 24 are formed on the connection pads 17, respectively, on the upper surface of the stack unit 18 to make an interposer 30. The interposer 30 shown in FIG. 5(b) is formed in exactly the same shape as the interposer 30 shown in FIG. 2(b). As shown in FIG. 3, by coupling the interposer 30 to the substrate 40, a wiring board having the interposer 30 is formed.

The method of fabricating the wiring board according to this embodiment has the advantage that the provision of the connection films in the same shape makes it possible to produce the interposer 30 with a stack of a required number of layers of the connection films 19.

The wiring board according to this invention is formed by coupling the interposer 30 to the substrate 40. This interposer 30 has a very effective function as a buffer. Even in the case where the thermal expansion coefficient of the semiconductor element 50 is considerably different from that of the substrate 40, therefore, the thermal stress acting on the semiconductor element 50 can be effectively suppressed.

As a result, a wiring board is provided on which a semiconductor, reduced in strength due to a higher operating speed and a higher degree of integration, can be suitably mounted. Also, even a bulky semiconductor element which has conventionally been impossible to mount on a board due to a large effect of thermal stress can be sufficiently mounted on the wiring board according to the invention.

This invention provides a wiring board in which, even in the case where the thermal expansion coefficient of the semiconductor element is greatly different from that of the substrate, the thermal stress generated between the semiconductor element and the substrate can be effectively relaxed, so that even a semiconductor element of low strength can be suitably mounted, thereby providing a highly reliable semiconductor device. Also, even a large semiconductor element, which has hitherto been impossible to mount on the conventional wiring board, can be mounted on the wiring board according to the invention. Therefore, the semiconductors used for various applications can be mounted on the wiring board according to this invention.

Further, the method of fabricating a wiring board according to the invention has the advantages that the interposer with the via conductors connected in columns can be readily formed and a wiring board having the buffer function conforming with a target product can be fabricated by appropriately adjusting the number of the via conductors stacked.

1. A wiring board comprising:
a substrate having a surface on which a plurality of connecting electrodes are arranged;
an interposer provided with via conductors arranged so as to conform to an arrangement of a plurality of electrodes formed on an electrode forming surface of a semiconductor element to be mounted, so that, when the semiconductor element is mounted on the substrate, the respective electrodes of the semiconductor element are electrically connected to the respective connecting electrodes of the substrate through respective via conductors of the interposer; and
the interposer comprising a plurality of insulating layers laminated in thickness direction thereof, each layer having a plurality of filled vias penetrating in a thickness direction thereof, to form columns.

2. A wiring board comprising as set forth claim 1, wherein the via connectors of the interposer are electrically connected to the connecting electrodes of the substrate by means of bumps.

3. A wiring board comprising as set forth claim 1, wherein the interposer has an element mounting surface on which a plurality of solder bumps are arranged and electrically connected to the respective via conductors.

4. A wiring board comprising as set forth claim 1, wherein the interposer has an semiconductor element mounting surface on which a plurality of connecting pads are arranged and electrically connected to the via conductors.

5. A semiconductor device comprising:
a semiconductor element having an electrode forming surface on which of a plurality of electrodes are formed;
a substrate having a surface on which a plurality of connecting electrodes are arranged;
an interposer provided with via conductors arranged so as to conform to an arrangement of the electrodes of the semiconductor element, so that the semiconductor element is flip-chip mounted in such a manner that the respective electrodes of the semiconductor element are electrically connected to the respective connecting electrodes of the substrate through the respective via conductors of the interposer; and
the interposer comprising a plurality of insulating layers laminated in thickness direction thereof, each layer having a plurality of filled vias penetrating in a thickness direction thereof, to form columns.

6. A semiconductor device as set forth claim 5, wherein the via connectors of the interposer are electrically connected to the connecting electrodes of the substrate by means of bumps.

7. A semiconductor device as set forth claim 5, wherein the interposer has an element mounting surface on which a plurality of solder bumps are arranged and electrically connected to the respective via conductors.

8. A semiconductor device as set forth claim 5, wherein the interposer has a semiconductor element mounting surface on which a plurality of connecting pads are arranged and electrically connected to the respective via conductors.

9. A process for fabricating a wiring board comprising the following steps of:
forming a first insulating layer with first via holes and filling the first via holes with first via conductor; forming a second insulating layer on the first insulating layer, forming second insulating layer with second via holes in registry with the first via conductors, and filling the second via holes with second via conductor; and repeating these steps to form an interposer in which the plurality of insulating layers are integrally stacked so that the plurality of conductor vias are mutually and electrically connected with the conductor vias of the adjacent layers in a thinness direction of thus formed laminated body; and
abutting the interposer to a substrate in such a manner that the via conductors of the interposer are electrically connected to respective connecting electrodes of the substrate.

10. A process for fabricating a wiring board comprising the following steps of:
preparing a plurality of connection films, each comprising an insulating layer provided with a plurality of conductor vias formed as filled vias penetrating the insulating layer in a thickness direction thereof; and
integrally stacking the plurality of connection films in registry with each other to laminate the plurality of insulating layers so that the plurality of conductor vias are mutually and electrically connected with the conductor vias of the adjacent layers in a thinness direction of the thus formed laminated body to form an interposer; and
abutting the interposer to a substrate in such a manner that the via conductors of the interposer are electrically connected to respective connecting electrodes of the substrate.
